(19) United States
(12) Patent Application Publication
(10) Pub. No.: US 2024/0204076 A1
(43) Pub. Date: Jun. 20, 2024

(54) Thin Film Transistor, Fabrication Method Thereof, and Display Apparatus Comprising the Same

(71) Applicant: LG Display Co., Ltd., Seoul (KR)

(72) Inventors: KyungChul Ok, Paju-si (KR); Uyhyun Choi, Paju-si (KR); SeungChan Choi, Paju-si (KR); Min-Gu Kang, Paju-si (JP); Jaeman Jang, Paju-si (KR); DaeHwan Kim, Paju-si (KR); Seoyeon Im, Paju-si (KR)

(21) Appl. No.: 18/461,336

(22) Filed: Sep. 5, 2023

(30) Foreign Application Priority Data
Dec. 19, 2022 (KR) 10-2022-0178040

(51) Int. Cl. H01L 29/49; H01L 29/40; H01L 29/423; H01L 29/66; H01L 29/786

(52) U.S. Cl. CPC H01L 29/4908; H01L 29/401; H01L 29/42384; H01L 29/66969; H01L 29/78606; H01L 29/7869; H01L 21/02126

(57) ABSTRACT

The thin film transistor, fabrication method thereof, and display apparatus comprising the same are provided. The thin film transistor comprises a base substrate, an oxide semiconductor layer on the base substrate, a channel protection layer in contact with the oxide semiconductor layer, and a gate electrode spaced apart from the oxide semiconductor layer and at least partially overlapped with the oxide semiconductor layer, and the channel protection layer includes carbon.

### CROSS-REFERENCE TO RELATED APPLICATIONS

This application claims the benefit of and priority to Republic of Korea Patent Application No. 10-2022-0178040 filed on Dec. 19, 2022, which is incorporated herein by reference in its entirety.

### TECHNICAL FIELD

The present disclosure relates to a thin film transistor, a fabricating method thereof, and a display apparatus including the thin film transistor.

### BACKGROUND

Transistors are widely used as switching devices or driving devices in the field of electronic apparatuses. In particular, since a thin film transistor can be manufactured on a glass substrate or a plastic substrate, the thin film transistor is widely used as a switching device of a display apparatus such as a liquid crystal display apparatus or an organic light emitting apparatus.

An oxide constituting an active layer of an oxide semiconductor thin film transistor may be grown at a relatively low temperature, and the oxide semiconductor thin film transistor has high mobility, and has a large resistance change in accordance with an oxygen content, whereby desired properties may be easily obtained. Further, in view of the properties of the oxide, since an oxide semiconductor is transparent, it is favorable to embody a transparent display.

In oxide semiconductors, electrons mainly function as carriers, and the characteristics of oxide semiconductor thin film transistors may vary due to changes in electron concentration. For example, if electrons are trapped in Non Bonding Oxygen (NBO) formed at the interface between the gate insulating layer and the oxide semiconductor layer, the threshold voltage of the oxide semiconductor thin film transistor may shift in a positive direction due to a decrease in electrons. When the threshold voltage changes, the operation of the thin film transistor is not constant, which reduces the reliability of the thin film transistor, and the display quality of the display apparatus using the thin film transistor may decrease.

In addition, when the oxide semiconductor thin film transistor (Oxide semiconductor TFT) is driven on for a long time, the threshold voltage tends to change continuously. Therefore, it is necessary to improve the driving stability of the oxide semiconductor thin film transistor.

### SUMMARY

The present disclosure has been made in view of the above problems and it is an object of the present disclosure to provide a thin film transistor that can prevent the deterioration of the oxide semiconductor layer by suppressing or preventing the generation of electron traps at the interface of the oxide semiconductor layer when the thin film transistor is driven.

It is another object of the present disclosure to provide a display device including such a thin film transistor.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor comprising a base substrate, an oxide semiconductor layer on the base substrate, a channel protection layer in contact with the oxide semiconductor layer, and a gate electrode spaced apart from the oxide semiconductor layer and at least partially overlapped with the oxide semiconductor layer, and the channel protection layer includes carbon.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1A is a plan view of a thin film transistor according to an embodiment of the present disclosure.

FIG. 1B is a cross-sectional view taken along line I-I′ of FIG. 1A according to an embodiment of the present disclosure.

FIG. 2 is a cross-sectional view of a thin film transistor according to another embodiment of the present disclosure.

FIG. 3 is a cross-sectional view of a thin film transistor according to still another embodiment of the present disclosure.

FIG. 4 is a cross-sectional view of a thin film transistor according to still another embodiment of the present disclosure.

FIG. 5 is a cross-sectional view of a thin film transistor according to still another embodiment of the present disclosure.

FIG. 6 is a cross-sectional view of a thin film transistor according to still another embodiment of the present disclosure.

FIG. 7 is a cross-sectional view of a thin film transistor according to still another embodiment of the present disclosure.

FIG. 8A is a schematic diagram illustrating an electronic trap of a thin film transistor according to an embodiment of the present disclosure.

FIG. 8B is a schematic diagram illustrating an electron trap of a thin film transistor according to an embodiment of the present disclosure.

FIG. 9 is a graph illustrating PBTS of thin film transistors according to embodiments and comparative examples according to an embodiment of the present disclosure.

FIG. 10 is a schematic diagram illustrating an arrangement and binding state of carbon C at a channel protection layer interface according to an embodiment of the present disclosure.

FIG. 11A is a cross-sectional view of a thin film transistor according to a comparative example according to one embodiment of the present disclosure.

FIG. 11B is an EDS graph of the thin film transistor according to FIG. 11A according to one embodiment of the present disclosure.

FIG. 12A is a cross-sectional view of a thin film transistor according to an embodiment of the present disclosure.

FIG. 12B is an EDS graph of the thin film transistor according to FIG. 12A according to one embodiment of the present disclosure.

FIG. 13 is a graph illustrating a carbon (C) surface density fraction and mobility of a thin film transistor according to an embodiment of the present disclosure.

FIGS. 14A to 14G are process view of a method of fabricating a thin film transistor according to an embodiment of the present disclosure.

FIG. 15 is a schematic diagram of a display apparatus according to an embodiment of the present disclosure.

FIG. 16 is a schematic diagram of a shift register according to an embodiment of the present disclosure.

FIG. 17 is a circuit view of any one pixel of FIG. 15 according to an embodiment of the present disclosure.

FIG. 18 is a circuit view of any one pixel of a display apparatus according to another embodiment of the present disclosure.

FIG. 19 is a circuit view of any one pixel of a display apparatus according to still another embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

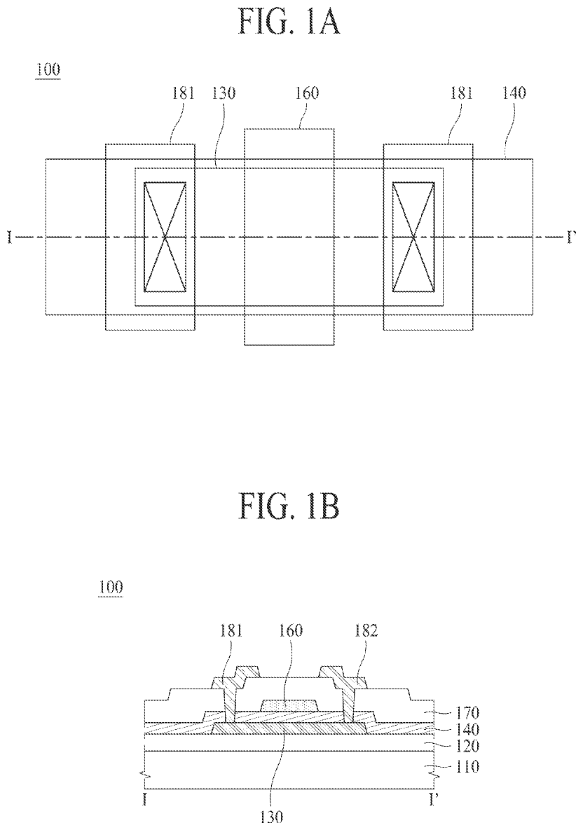

FIG. 1A is a plan view of a thin film transistor 100 according to an embodiment of the present disclosure.

FIG. 1B is a cross-sectional view taken along line I-I′ of FIG. 1A.

Referring to FIGS. 1A and 1B, the thin film transistor 100 according to an embodiment of the present disclosure may include a base substrate 110, an oxide semiconductor layer 130, a channel protection layer 140, and a gate electrode 160.

Specifically, FIG. 1A and FIG. 1B include a base substrate 110, an oxide semiconductor layer 130 on a base substrate, a channel protection layer 140 in contact with the oxide semiconductor layer 130, and a gate electrode 160 spaced apart from the oxide semiconductor layer 130 and at least partially overlapped with the oxide semiconductor layer 130.

The thin film transistor 100 may further include a buffer layer 120. Referring to FIG. 1B, the oxide semiconductor layer 130 is disposed on the buffer layer 120. Specifically, the buffer layer 120 is disposed between the base substrate 110 and the oxide semiconductor layer 130.

Hereinafter, components of the thin film transistor 100 according to an embodiment of the present disclosure will be described in more detail.

Glass or plastic may be used as the base substrate 110. Transparent plastic having flexible properties as plastic, for example, polyimide, may be used.

When polyimide is used as a base substrate 110, heat-resistant polyimide that can withstand high temperatures may be used considering that a high-temperature deposition process is performed on the base substrate 110. In this case, in order to form a thin film transistor, processes such as deposition and etching can be carried out while the polyimide substrate is placed on a carrier substrate made of a high durability material such as glass.

Referring to FIGS. 1A and 1B, a buffer layer 120 may be disposed on the base substrate 110.

The buffer layer 120 is formed on the base substrate 110 and may be formed of an inorganic material or an organic material. For example, insulating oxides such as silicon oxide (SiOx) and aluminum oxide (Al₂O₃) may be included.

The buffer layer 120 may be formed as a single layer or multiple layers to protect the oxide semiconductor layer 130, planarize an upper part of the base substrate 110, and block impurities such as moisture and oxygen introduced from the base substrate 110.

According to an embodiment of the present disclosure, the oxide semiconductor layer 130 may be disposed on the buffer layer 120. Specifically, FIG. 1B illustrates a configuration in which the oxide semiconductor layer 130 is disposed on the buffer layer 120.

According to an embodiment of the present disclosure, the oxide semiconductor layer 130 includes an oxide semiconductor material. For example, the oxide semiconductor layer 130 may include at least one of IZO(InZnO)-based oxide semiconductor material, IGO(InGaO)-based oxide semiconductor material, ITO(InSnO)-based oxide semiconductor material, IGZO(InGaZnO)-based oxide semiconductor material, IGZTO(InGaZnSnO)-based oxide semiconductor material, GZTO(GaZnSnO)-based oxide semiconductor material, GZO(GaZnO)-based oxide semiconductor material, and GO(GaO)-based oxide semiconductor material and ITZO(InSnZnO)-based oxide semiconductor material. However, one embodiment of present disclosure is not limited to this, and an oxide semiconductor layer 130 may be made by other oxide semiconductor materials known in the art.

According to an embodiment of the present disclosure, the channel protection layer 140 may be in contact with the oxide semiconductor layer 130. Specifically, FIG. 1B illustrates a configuration in which the channel protection layer 140 is disposed on the oxide semiconductor layer 130. However, one embodiment of present disclosure is not limited to this, and the oxide semiconductor layer 130 may contact the channel protection layer 140 and the oxide semiconductor layer 130 may be disposed on the channel protection layer 140. The channel protection layer 140 will be described in detail below.

The thin film transistor 100 according to an embodiment of the present disclosure includes a gate electrode 160. The gate electrode 160 according to an embodiment of the present disclosure is disposed on the oxide semiconductor layer 130 and the channel protection layer 140. Referring to FIGS. 1A and 1B, the gate electrode 160 may be in contact with the channel protection layer 140. Specifically, the channel protection layer 140 may be disposed between the oxide semiconductor layer 130 and the gate electrode 160. However, one embodiment of present disclosure is not limited to this, and another layer may be placed between the channel protection layer 140 and the gate electrode 160. Specifically, gate insulating layers 250, 350, 450, and 650 may be disposed between the channel protection layer 140 and the gate electrode 160.

The gate electrode 160 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti). Although not shown, the gate electrode 150 may have a multi-layered structure that includes two conductive layers having their respective physical properties different from each other.

The thin film transistor 100 may further include an interlayer insulating layer 170. Specifically, referring to FIG. 1B, an interlayer insulating layer 170 may be disposed on the gate electrode 160.

The interlayer insulating layer 170 is an insulating layer made of an insulating material. Specifically, the interlayer insulating layer 170 may be made of an organic material, an inorganic material, or a laminate of an organic material layer and an inorganic material layer.

According to an embodiment of the present disclosure, the thin film transistor 100 may include a source electrode 181 and a drain electrode 182. The source electrode 181 and the drain electrode 182 may be disposed on the interlayer insulating layer 170 as illustrated in FIG. 1B.

The source electrode 181 and the drain electrode 182 may be spaced apart from each other and connected to the oxide semiconductor layer 130, respectively. Referring to FIG. 1A and FIG. 1B, the source electrode 181 and the drain electrode 182 are connected to the oxide semiconductor layer 130 through contact holes, respectively.

The source electrode 181 and drain electrode 182 may each contain at least one of molybdenum (Mo), aluminum (Al), chromium (Cr), gold (Au), titanium (Ti), nickel (Ni), neodymium (Nd), copper (Cu), and alloys thereof. The source electrode 181 and the drain electrode 182 may each consist of a single layer made of a metal or an alloy of metal, or may consist of two or more layers.

Hereinafter, the channel protection layer 140 will be described in more detail.

According to an embodiment of the present disclosure, the channel protection layer 140 refers to an insulating layer including carbon (C). The channel protection layer 140 may be disposed between the oxide semiconductor layer 130 and the gate electrode 160. Specifically, FIG. 1A and FIG. 1B illustrate the configuration in which the channel protection layer 140 is disposed between the oxide semiconductor layer 130 and the gate electrode 160. However, one embodiment of present disclosure is not limited to this, and the channel protection layer 140 may be disposed between the oxide semiconductor layer 130 and the base substrate 110.

According to an embodiment of the present disclosure, the channel protection layer 140 may be in contact with the side surface of the oxide semiconductor layer 130. Specifically, the channel protection layer 140 may surround an upper surface and a side surface of the oxide semiconductor layer 130. Referring to FIG. 1B, the channel protection layer 140 may be in contact with at least a part of the buffer layer 120. In an exemplary embodiment, the channel protection layer 140 may be in contact with one or both the upper and bottom surfaces of the oxide semiconductor layer 130. In a further exemplary embodiment, the channel protection layer 140 may be formed between the gate electrode 160 and the oxide semiconductor layer 130 to cover an area that the gate electrode 160 overlaps with the oxide semiconductor layer 130 in vertical direction.

Non Bonding Oxygen (NBO) may exist at the interface between the oxide semiconductor layer 130 and the channel protection layer 140. Non Bonding Oxygen (NBO) refers to a state in which oxygen (O) does not have a sufficient bond state and thus further bonding with other elements is possible. As a result, Non Bonding Oxygen (NBO) can trap electrons present in the channel portion of the oxide semiconductor layer 130. When electrons, which are carriers of the channel, are trapped in Non Bonding Oxygen (NBO), the threshold voltage of the thin film transistor 100 including the oxide semiconductor layer 130 may shift in the direction of positive due to a decrease in electrons, which are carriers. When the threshold voltage changes, the driving of the thin film transistor 100 is not constant, and thus the reliability of the thin film transistor 100 may be reduced.

Therefore, the channel protection layer 140 according to an embodiment of present disclosure may include carbon (C) to prevent or suppress electrons from being trapped in Non Bonding Oxygen (NBO).

Carbon (C) is a material with high oxidation properties and has a strong bonding force with oxygen (O). As a result, carbon (C) can be combined with Non Bonding Oxygen (NBO) to effectively reduce Non Bonding Oxygen (NBO). As a result, carbon (C) may effectively control Non Bonding Oxygen (NBO).

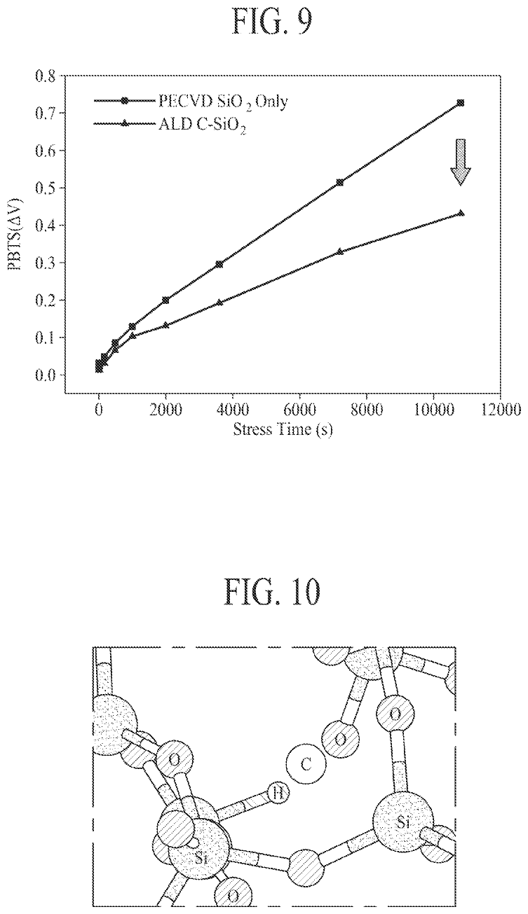

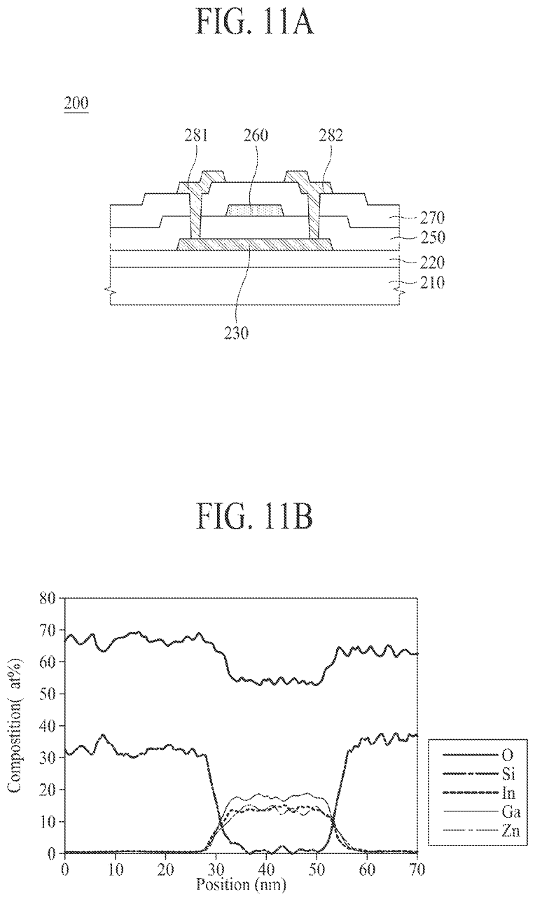

Specifically, FIG. 10 is a schematic diagram illustrating an arrangement and binding state of carbon C at a channel protection layer interface. When the channel protection layer 140 includes carbon (C), carbon (C) may be combined with Non Bonding Oxygen (NBO) to prevent or control electrons, which are carriers present in the oxide semiconductor layer 130, from being trapped in Non Bonding Oxygen (NBO).

According to an embodiment of the present disclosure, the channel protection layer 140 may include silicon (Si), oxygen (O), and carbon (C). The channel protection layer 140 in accordance with an embodiment of present disclosure may have insulating properties, and the carbon (C) concentration of the channel protection layer may be 1 to 10% by atom (at %). Specifically, the concentration of carbon (C) in the channel protection layer 140 can be 1 to 10% by atom (at %) based on the entire components of the channel protection layer 140.

If the concentration of carbon (C) in the channel protection layer 140 is less than 1% by atom (at %), the Non Bonding Oxygen (NBO) present at the interface of the channel protection layer 140 and carbon (C) cannot sufficiently combine, so that Non Bonding Oxygen (NBO) present at the interface of channel protection layer 140 can trap electrons. Accordingly, the threshold voltage of the thin film transistor 100 may shift in a positive direction. As a result, since the driving of the thin film transistor 100 is not constant, the reliability of the thin film transistor 100 may be reduced.

On the other hand, if the concentration of carbon (C) in the channel protection layer 140 is more than 10 atomic %, an excessive amount of carbon (C) is present in the channel protection layer 140, and mobility of carriers present in the channel may decrease due to strong oxygen (O) stabilization bonds in the oxide semiconductor layer 130. As a result, the reliability of the thin film transistor 100 may be reduced.

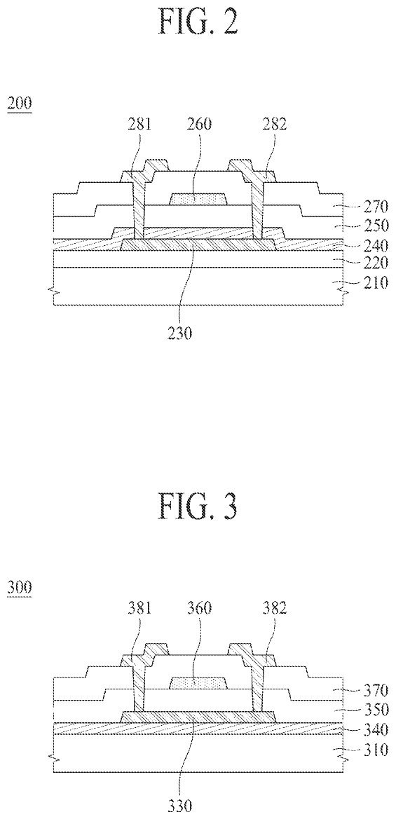

FIG. 2 is a cross-sectional view of a thin film transistor 200 according to another embodiment of the present disclosure. Specifically, FIG. 2 is a cross-sectional view of a surface corresponding to FIG. 1B. Hereinafter, the same contents are omitted.

Referring to FIG. 2, the thin film transistor 200 according to an embodiment of the present disclosure may further include a gate insulating layer 250.

In the thin film transistor 200 according to an embodiment of the present disclosure, a gate insulating layer 250 may be disposed on the channel protection layer 240. Specifically, referring to FIG. 2, the gate insulating layer 250 is disposed between the channel protection layer 240 and the gate electrode 260. According to an embodiment of the present disclosure, a gate insulating layer 250 may be disposed over the entire upper portion of the base substrate 210 including the upper portion of the oxide semiconductor layer 230. As a result, the oxide semiconductor layer 230 may be effectively protected by the gate insulating layer 250. In particular, during the etching process for the gate electrode 260, metal materials contained in the oxide semiconductor layer 230 can be re-deposited on the sidewall of the gate insulating layer 250 to prevent an electrical short between the gate electrode 260 and the oxide semiconductor layer 230.

The gate insulating layer 250 may include at least one of silicon oxide, silicon nitride, and metal oxide. The gate insulating layer 250 may have a single layer structure or a multilayer layer structure.

According to an embodiment of present disclosure, the channel protection layer 240 may include silicon (Si), oxygen (O), hydrogen (H), and carbon (C), and the gate insulation layer 250 may include silicon (Si), oxygen (O), and hydrogen (H). However, one embodiment of present disclosure is not limited to this, and the gate insulating layer 250 may contain carbon (C), and the gate insulating layer 250 may not contain carbon (C).

According to an embodiment of the present disclosure, when the gate insulating layer 250 includes carbon (C), the carbon (C) concentration (at %) of the channel protection layer 240 may be 100 times or more of the carbon (C) concentration (at %) of the gate insulating layer 250.

According to an embodiment of the present disclosure, the hydrogen (H) concentration (at %) of the channel protection layer 240 may be lower than the hydrogen (H) concentration (at %) of the gate insulating layer 250.

According to an embodiment of the present disclosure, the channel protection layer 240 may include Non Bonding Oxygen (NBO), the gate insulation layer 250 may include Non Bonding Oxygen (NBO), and the Non Bonding Oxygen density of the channel protection layer 240 may be lower than the Non Bonding Oxygen density of the gate insulation layer 250.

The density of Non Bonding Oxygen (NBO) described above refers to the ratio of Non Bonding Oxygen (NBO, at %) to the total oxygen (at %) of the layer.

Referring to FIG. 2, the channel protection layer 240 may have a thickness thinner than that of the gate insulating layer 250. Specifically, according to an embodiment of the present disclosure, the channel protection layer 240 may have a thickness in the range of 1 to 10 nm.

According to an embodiment of the present disclosure, the channel protection layers 140 and 240 may be in contact with the gate electrodes 160 and 260. Referring to FIG. 1B, a gate insulating layer 250 may not be included between the channel protection layer 140 and the gate electrode 160. Specifically, according to an embodiment of the present disclosure, the channel protection layer 140 may have a thickness in the range of 10 to 100 nm.

FIG. 3 is a cross-sectional view of a thin film transistor 300 according to another embodiment of the present disclosure.

According to an embodiment of the present disclosure, the channel protection layer 340 may be disposed between the base substrate 310 and the oxide semiconductor layer 330. Specifically, referring to FIG. 3, the channel protection layer 340 may be in contact with the entire bottom surface of the oxide semiconductor layer 330. FIG. 3 illustrates a configuration in which the channel protection layer 340 is not in contact with the side surface of the oxide semiconductor layer 330. However, one embodiment of present disclosure is not limited to this, and the channel protection layer 340 may contact at least some of the side surfaces of the oxide semiconductor layer 330.

According to one embodiment of present disclosure, even if the channel protection layer 340 contacts with the lower surface of the oxide semiconductor layer 330, carbon (C) can be combined with Non Bonding Oxygen (NBO) to prevent or control electrons, which are carriers present in the oxide semiconductor layer 330, from being trapped in the Non Bonding Oxygen (NBO).

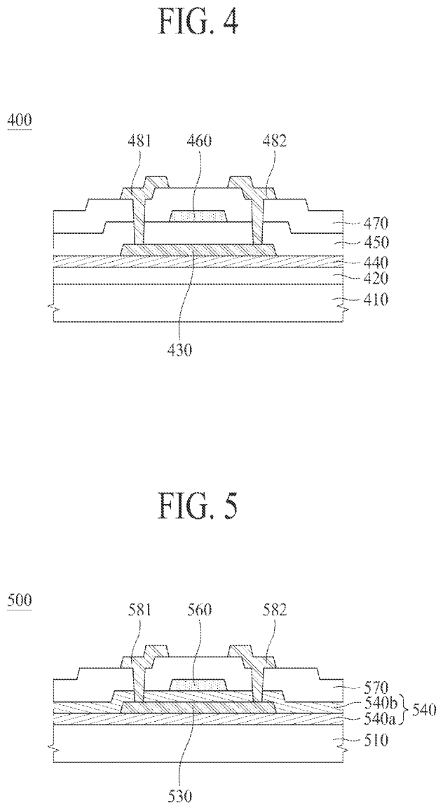

FIG. 4 is a cross-sectional view of a thin film transistor 400 according to another embodiment of the present disclosure.

Referring to FIG. 4, compared with FIG. 3, the thin film transistor 400 according to an embodiment of the present disclosure may further include a buffer layer 420. Specifically, the buffer layer 420 may be disposed between the channel protection layer 440 and the base substrate 410.

According to an embodiment of present disclosure, the channel protection layer 440 may include silicon (Si), oxygen (O), hydrogen (H), and carbon (C), and the buffer layer 420 may include silicon (Si), oxygen (O), and hydrogen (H), but the embodiment of present disclosure is not limited thereto, and the buffer layer 420 may include carbon (C), and may not include carbon (C).

According to an embodiment of the present disclosure, when the buffer layer 420 includes carbon C, the carbon concentration (at %) of the channel protection layer 440 may be 100 times or more of the carbon (C) concentration (at %) of the buffer layer 420.

According to an embodiment of the present disclosure, the hydrogen (H) concentration (at %) of the channel protection layer 440 may be lower than the hydrogen (H) concentration (at %) of the buffer layer 420.

According to an embodiment of present disclosure, the channel protection layer 440 may include Non Bonding Oxygen (NBO), the buffer layer 420 may include Non Bonding Oxygen (NBO), and the density of Non Bonding Oxygen (NBO) of the channel protection layer 440 may be lower than the density of the Non Bonding Oxygen (NBO) of buffer layer 420.

The density of Non Bonding Oxygen (NBO) described above refers to the ratio of Non Bonding Oxygen (NBO) to the total oxygen of the layer.

Referring to FIG. 4, the channel protection layer 440 may have a thickness thinner than that of the buffer layer 420. Specifically, according to an embodiment of the present disclosure, when the channel protection layer 440 is disposed between the buffer layer 420 and the oxide semiconductor layer 430, the channel protection layer 440 may have a thickness in the range of 1 to 10 nm.

According to an embodiment of the present disclosure, the channel protection layer 440 may be in contact with the base substrate 410. Referring to FIG. 3, a buffer layer 420 may not be included between the channel protection layer 340 and the base substrate 310. Specifically, according to an embodiment of the present disclosure, when the channel protection layer 340 is disposed between the base substrate 310 and the oxide semiconductor layer 330, the channel protection layer 340 may have a thickness in the range of 10 to 100 nm.

FIG. 5 is a cross-sectional view of a thin film transistor 500 according to another embodiment of the present disclosure.

According to an embodiment of present disclosure, the channel protection layer 540 may include a first channel protection layer 540a and a second channel protection layer 540b, and the oxide semiconductor layer 530 may be disposed between the first channel protection layer 540a and the second channel protection layer 540b. FIG. 5 shows a configuration in which an oxide semiconductor layer 530 is disposed between the first channel protection layer 540a and the second channel protection layer 540b.

Specifically, referring to FIG. 5, the first channel protection layer 540a may be in contact with the lower surface of the oxide semiconductor layer 530, and the second channel protection layer 540b may be in contact with the upper surface of the oxide semiconductor layer 530. More specifically, the first channel protection layer 540a may cover the entire lower surface of the oxide semiconductor layer 530, and the second channel protection layer 540b may cover the entire upper surface of the oxide semiconductor layer 530.

According to one embodiment of present disclosure, at least one of the first channel protection layer 540a and the second channel protection layer 540b may be in contact with the side surface of the oxide semiconductor layer 530. Referring to FIG. 5, the second channel protection layer 540b covers a side surface of the oxide semiconductor layer 530. However, one embodiment of present disclosure is not limited to this, and the first channel protection layer 540a may cover the side surface of the oxide semiconductor layer 530.

According to an embodiment of the present disclosure, at least a part of the first channel protection layer 540a and at least a part of the second channel protection layer 540b may be in contact with each other. Specifically, referring to FIG. 5, the first channel protection layer 540a and the second channel protection layer 540b may be in contact with each other in a region that does not overlap the oxide semiconductor layer 530.

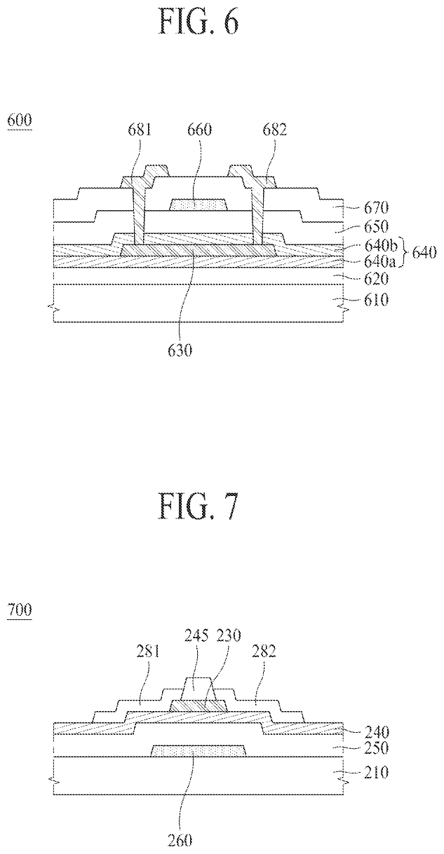

FIG. 6 is a cross-sectional view of a thin film transistor 600 according to another embodiment of the present disclosure.

Referring to FIG. 6, compared with FIG. 5, the thin film transistor 600 according to an embodiment of the present disclosure may further include a buffer layer 620. Specifically, according to an embodiment of the present disclosure, the buffer layer 620 may be disposed between the first channel protection layer 640a and the base substrate 610.

Referring to FIG. 6, in comparison with FIG. 5, the thin film transistor 600 according to an embodiment of the present disclosure may further include a gate insulating layer 650. Specifically, according to an embodiment of the present disclosure, the gate insulating layer 650 may be disposed between the second channel protection layer 640b and the gate electrode 660.

FIG. 7 is a cross-sectional view of a thin film transistor 700 according to still another embodiment of the present disclosure.

The thin film transistor 700 of FIG. 7 includes a gate electrode 260 on the base substrate 210, a gate insulating layer 250 on the gate electrode 260, an oxide semiconductor layer 230 on the channel protection layer 240, a source electrode 281, and a drain electrode 282 connected to the oxide semiconductor layer 230. Referring to FIG. 7, the thin film transistor 700 may further include an etch stopper layer 245.

Referring to FIG. 7, a gate electrode 260 is disposed between the base substrate 210 and the oxide semiconductor layer 230. As shown in FIG. 7, the structure in which the gate electrode 260 is placed under the oxide semiconductor layer 230 is called a bottom gate structure. Since the oxide semiconductor layer 230 and the channel protection layer 240 have already been described, detailed descriptions thereof will be omitted.

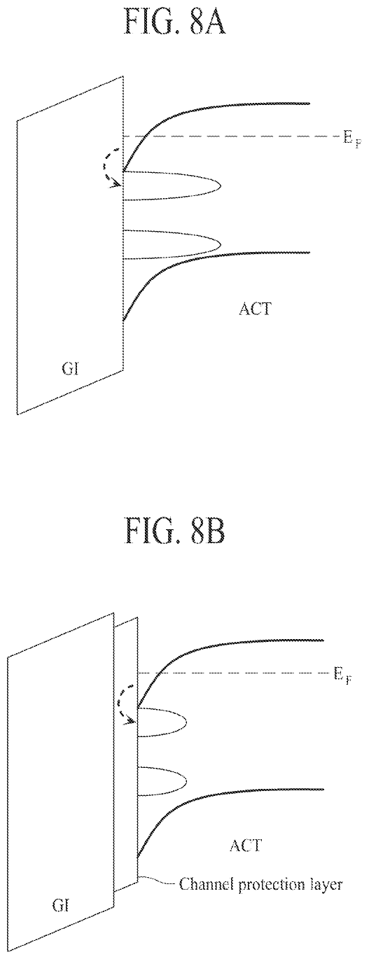

FIGS. 8A and 8B are schematic diagrams illustrating an electronic trap of a thin film transistor.

Referring to FIG. 8A, in the absence of a channel protection layer 240, electrons may be trapped in Non Bonding Oxygen (NBO) present at the interface of the oxide semiconductor layer 230.

On the other hand, referring to FIG. 8B, a channel protection layer 240 may exist between the gate insulating layer 250 and the oxide semiconductor layer 230. The channel protection layer 240 includes carbon C, and if carbon (C) present at the interface of channel protection layer 240 is combined with non-bonding oxygen (NBO) to effectively control non-bonding oxygen (NBO), carbon (C) may be combined with Non Bonding Oxygen (NBO) to prevent or control electrons, which are carriers present in the channel of the oxide semiconductor layer 230, from being trapped in Non Bonding Oxygen (NBO).

FIG. 9 is a graph illustrating PBTSs of thin film transistors according to embodiments and comparative examples.

Referring to FIG. 9, the thin film transistor 100 according to an embodiment includes a channel protection layer 140. On the other hand, the thin film transistor according to the comparative example does not include the channel protection layer 140.

PBTS (Positive Bias Temperature Stress) refers to the stress that a thin film transistor receives under the condition that a positive (+) bias voltage is applied at a certain temperature, and generally has a positive (+) value. When the PBTS increases, the stress of the oxide semiconductor layer 130 and the thin film transistor increases, and the threshold voltage change ΔVth may increase.

Referring to FIG. 9, the thin film transistor according to the comparative example does not include a channel protection layer 140, and as a result, an electron trap may be generated in Non Bonding Oxygen (NBO), which may increase the PBTS (Positive Bias Temperature Stress). Accordingly, the stress of the oxide semiconductor layer 130 and the thin film transistor increases, and the threshold voltage change ΔVth may increase.

On the other hand, referring to FIG. 9, the thin film transistor according to the embodiment includes a channel protection layer 140, and as a result, the electron trap may be suppressed or controlled in the Non Bonding Oxygen (NBO), thereby reducing the PBTS (Positive Bias Temperature Stress). Accordingly, the stress of the oxide semiconductor layer 130 and the thin film transistor is reduced, and the threshold voltage change ΔVth may be reduced.

FIG. 10 is a schematic diagram illustrating an arrangement and binding state of carbon C at a channel protection layer interface.

According to an embodiment of present disclosure, carbon (C) present at the interface of the channel protection layer 140 can be bonded to Non Bonding Oxygen (NBO). Carbon (C) is a material with high oxidation properties and has a strong bonding force with oxygen (O). As a result, carbon (C) can be combined with Non Bonding Oxygen (NBO) to effectively control Non Bonding Oxygen (NBO).

FIG. 11A is a cross-sectional view of a thin film transistor 200 according to a comparative example of the present disclosure.

FIG. 11A shows a configuration in which the channel protection layer 240 of the thin film transistor 200 is not placed between the oxide semiconductor layer 230 and the gate insulating layer 250.

FIG. 11B is an EDS graph of the thin film transistor according to FIG. 11A.

The horizontal axis of the graph of FIG. 11B refers to a region from the gate insulating layer 250 to the buffer layer 220. Specifically, the 30 to 50 nm portion of the horizontal axis refers to a region from the upper surface of the oxide semiconductor layer 230 (an active layer) to the lower surface of the oxide semiconductor layer 230 (an active layer). The vertical axis of the graph refers to the specific gravity of elements present in each region.

Referring to FIG. 11B, since 0 to 30 nm and 50 to 70 nm regions of the horizontal axis are mostly made of oxygen (O) and silicon (Si), and thus they correspond to the insulating layer 250, and since the 30 to 50 nm region further includes indium (In), gallium (Ga), and zinc (Zn), and thus it corresponds to the oxide semiconductor layer 230.

Referring to FIG. 11B, it can be seen that the oxygen (O) signal decreases between the oxide semiconductor layer 230 and the channel protection layer 240. In this case, the signal may correspond to the vertical axis of the graph of FIG. 11B.

Specifically, if the thin film transistor according to the comparative example does not contain a channel protection layer 240, carbon (C) cannot bind to Non Bonding Oxygen (NBO) at the interface of the oxide semiconductor layer 230, so Non Bonding Oxygen (NBO) present at the interface of the oxide semiconductor layer 230 may not exist stably.

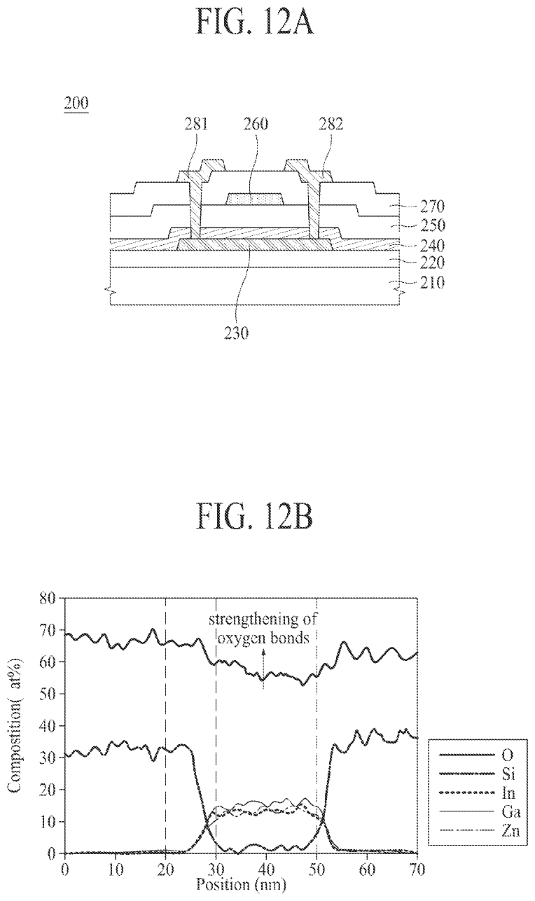

FIG. 12A is a cross-sectional view of a thin film transistor according to an embodiment.

FIG. 12A shows a configuration in which the channel protection layer 240 of the thin film transistor 200 is placed between the oxide semiconductor layer 230 and the gate insulating layer 250. However, an embodiment of present disclosure is not limited to this, and the channel protection layer 240 may be disposed between the oxide semiconductor layer 230 and the gate insulating layer 250.

FIG. 12B is an EDS graph of the thin film transistor according to FIG. 12A.

Referring to FIG. 12B, it may be seen that an oxygen (O) signal is increased at an interface of the oxide semiconductor layer 230.

Specifically, when the thin film transistor 200 includes a channel protection layer 240, carbon (C) is combined with Non Bonding Oxygen (NBO) at the interface of the oxide semiconductor layer 230, so that Non Bonding Oxygen (NBO) present at the interface of the oxide semiconductor layer 230 can exist stably. As a result, it may be seen that the specific gravity of oxygen present at the interface of the oxide semiconductor layer 230 has increased.

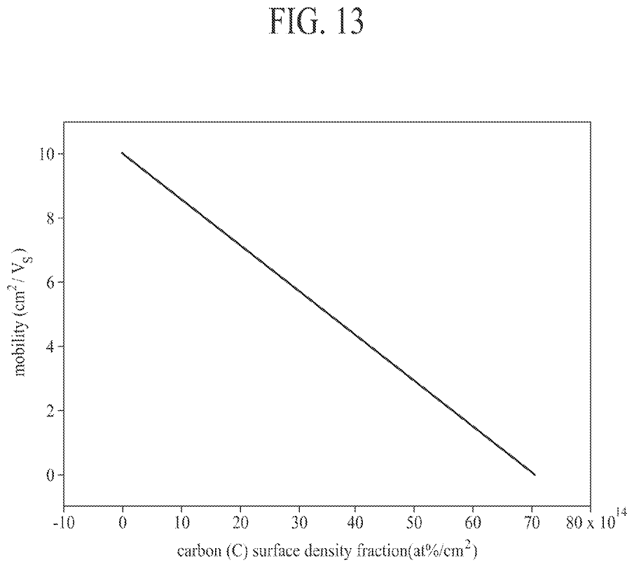

FIG. 13 is a graph illustrating a carbon (C) surface density fraction and mobility of a thin film transistor according to an embodiment of the present disclosure.

The thin film transistor according to an embodiment of the present disclosure may include channel protection layers 140, 240, 340, 440, 540, and 640. As a result, carbon (C) present at the channel protection layer interface binds to Non Bonding Oxygen (NBO), and electron trap in Non Bonding Oxygen (NBO) can be suppressed or controlled to improve the reliability of thin film transistors.

As described above, when the thin film transistor includes channel protection layers 140, 240, 340, 440, 540, 640, the reliability of the thin film transistor may be improved. On the other hand, when the concentration of carbon (C) is very high, the mobility of carriers present in the channel may decrease due to strong oxygen (O) stabilization bonds in the oxide semiconductor layers 130, 230, 330, 430, 530, and 630. Therefore, it is necessary to control the concentration of carbon (C) present at the interface of the channel protection layer 140, 240, 340, 440, 540, and 640.

According to an embodiment of present disclosure, the channel protection layers 140, 240, 340, 440, 540, and 640 may have a carbon (C) surface density fraction (Catoms/cm²) of 5.0×10¹⁵ or less, and the carbon (C) surface density fraction is calculated by the following Equation 1.

Carbon (C) surface density fraction (Catoms/cm²)=surface density (total number of atoms/cm²)×carbon (C) concentration (Cat %) [Equation 1]

In this case, the surface density (total number of atoms/cm²) means the surface density of the channel protection layers 140, 240, 340, 440, 540, and 640.

If the carbon (C) surface density fraction (number of C atomic×100/cm²) of the channel protection layer 140, 240, 340, 440, 540, and 640 exceeds 5.0×10¹⁵, mobility may decrease and the reliability of the thin film transistor may decrease.

Furthermore, if the carbon (C) surface density fraction (Catoms/cm²) is high, even if the thickness of the channel protection layer 140, 240, 340, 440, 540, 640 is thin, sufficient carbon (C) is contained to simultaneously secure the reliability and mobility of the channel, and even when the carbon (C) surface density fraction (Catoms/cm²) is low, the thicknesses of the channel protection layers 140, 240, 340, 440, 540, and 640 may be increased to simultaneously ensure reliability and mobility of the channel part.

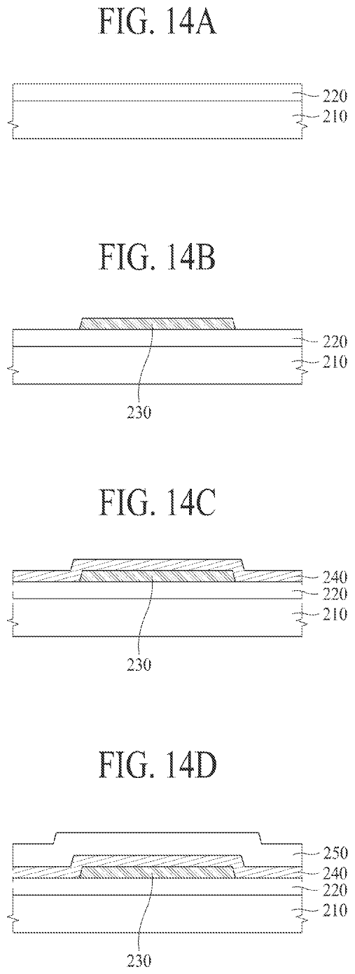

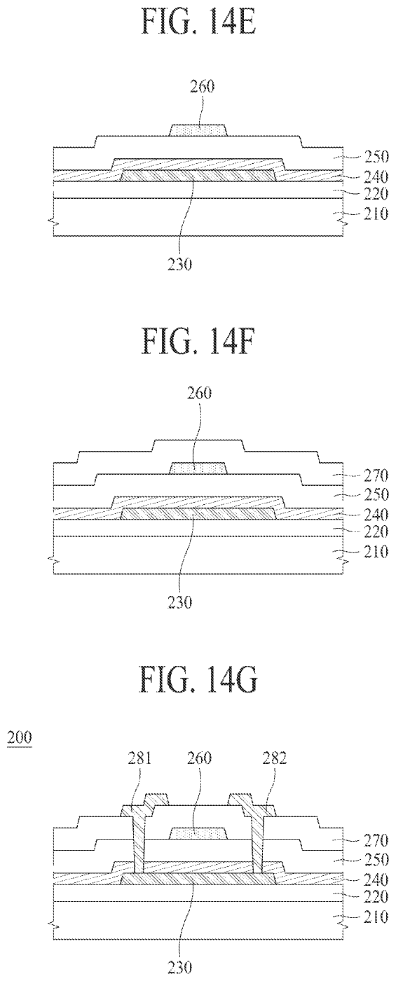

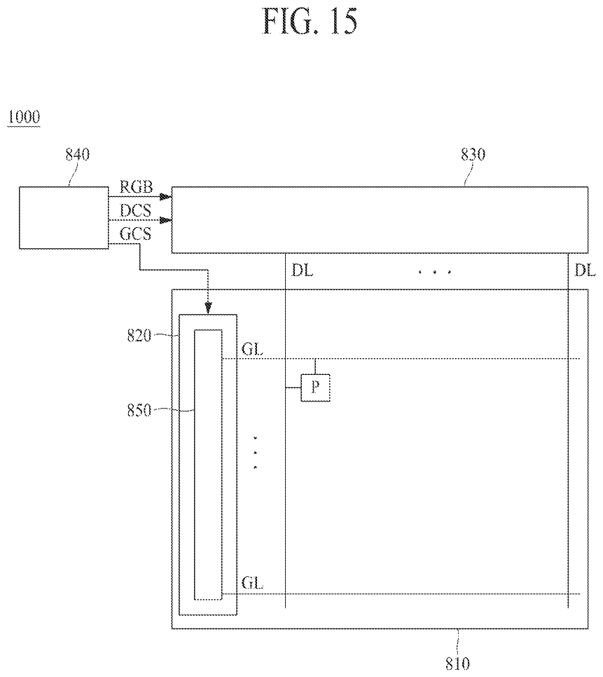

Hereinafter, a method of fabricating the thin film transistor 200 according to an embodiment of the present disclosure will be described with reference to FIGS. 14A to 14G.

FIGS. 14A to 14G are process view illustrating a method of fabricating a thin film transistor 200 according to an embodiment of the present disclosure.

Referring to FIG. 14A, a base substrate 210 is prepared, and a buffer layer 220 is formed on the base substrate 210. According to an embodiment of the present disclosure, a forming the buffer layer 220 on the base substrate 210 may be further included.

Referring to FIG. 14B, an oxide semiconductor layer 230 is formed on the base substrate 210. More specifically, the oxide semiconductor layer 230 is formed on the buffer layer 220.

Referring to FIG. 14C, a channel protection layer 240 is formed on the oxide semiconductor layer 230.

According to an embodiment of the present disclosure, the channel protection layer 240 may be deposited by an ALD or CVD method using a precursor, and the precursor may include at least one of di-isopropylaminosilane, (N,N-dimethylamino)trimethylsilane, vinyltrimethoxysilane, tetrakis(dimethylamino)silane, tris(dimethylamino)silane, bis(ethyl-methyl-amino)silane.

According to an embodiment of the present disclosure, forming the oxide semiconductor layer 230 may be performed before forming the channel protection layer 240. However, the embodiment according to present disclosure is not limited to this, and the forming the channel protection layer 240 may be performed before the forming the oxide semiconductor layer 230.

Referring to FIG. 14D, according to an embodiment of the present disclosure, a gate insulating layer 250 is formed on the oxide semiconductor layer 230. More specifically, the gate insulating layer 250 is formed on the channel protection layer 240.

Referring to FIG. 14E, a gate electrode 260 is formed on the channel protection layer 240. More specifically, the gate electrode 260 is formed on the gate insulating layer 250.

Referring to FIG. 14F, an interlayer insulating layer 270 is formed on the gate electrode 260.

Referring to FIG. 14G, a source electrode 281 and a drain electrode 282 are formed on the interlayer insulating layer 270.

FIG. 15 is a schematic view illustrating a display apparatus 1000 according to further still another embodiment of the present disclosure.

As shown in FIG. 15, the display apparatus 1000 according to further still another embodiment of the present disclosure may include a display panel 810, a gate driver 820, a data driver 830 and a controller 840.

The display panel 810 includes gate lines GL and data lines DL, and pixels P are disposed in intersection areas of the gate lines GL and the data lines DL. An image is displayed by driving the pixels P. The gate lines GL, the data lines DL and the pixels P may be disposed on the base substrate 110.

The controller 840 controls the gate driver 820 and the data driver 830.

The controller 840 outputs a gate control signal GCS for controlling the gate driver 820 and a data control signal DCS for controlling the data driver 830 by using a signal supplied from an external system not shown. Also, the controller 840 samples input image data input from the external system, realigns the sampled data and supplies the realigned digital image data RGB to the data driver 830.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 830 supplies a data voltage to the data lines DL of the display panel 810. In detail, the data driver 830 converts the image data RGB input from the controller 840 into an analog data voltage and supplies the data voltage to the data lines DL.

According to one embodiment of the present disclosure, the gate driver 820 may be packaged on the display panel 810. In this way, a structure in which the gate driver 820 is directly packaged on the display panel 810 will be referred to as a Gate In Panel (GIP) structure. In detail, in the Gate In Panel (GIP) structure, the gate driver 820 may be disposed on the base substrate 110.

The display apparatus 1000 according to one embodiment of the present disclosure may include the above-described thin film transistors 100, 200, 300, 400, 500 and 600. According to one embodiment of the present disclosure, the gate driver 320 may include the above-described thin film transistors 100, 200, 300, 400, 500 and 600.

The gate driver 820 may include a shift register 850.

The shift register 850 sequentially supplies gate pulses to the gate lines GL for one frame by using the start signal and the gate clock, which are transmitted from the controller 840. In this case, one frame means a time period at which one image is output through the display panel 810. The gate pulse has a turn-on voltage capable of turning on a switching device (thin film transistor) disposed in the pixel P.

Also, the shift register 850 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 850 may include the above-described thin film transistors 100, 200, 300, 400, 500 and 600.

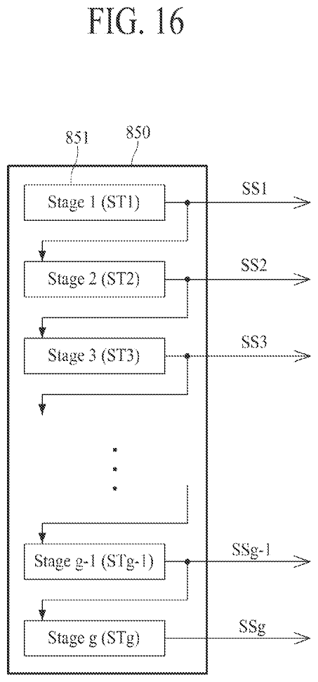

FIG. 16 is a schematic view illustrating a shift register 850.

Referring to FIG. 16, the shift register 850 may include g number of stages 851 (ST1 to STg).

The shift register 850 transmits one scan signal SS to pixels P connected to one gate line GL through one gate line GL. Each of the stages 851 may be connected to one gate line GL. When g number of gate lines GL are formed in the display panel 810, the shift register 850 may include g number of stages 851 (ST1 to STg), and may generate g number of scan signals SS1 to SSg.

In general, each stage 851 outputs the gate pulse GP once during one frame, and the gate pulses GP are sequentially output from each stage 851.

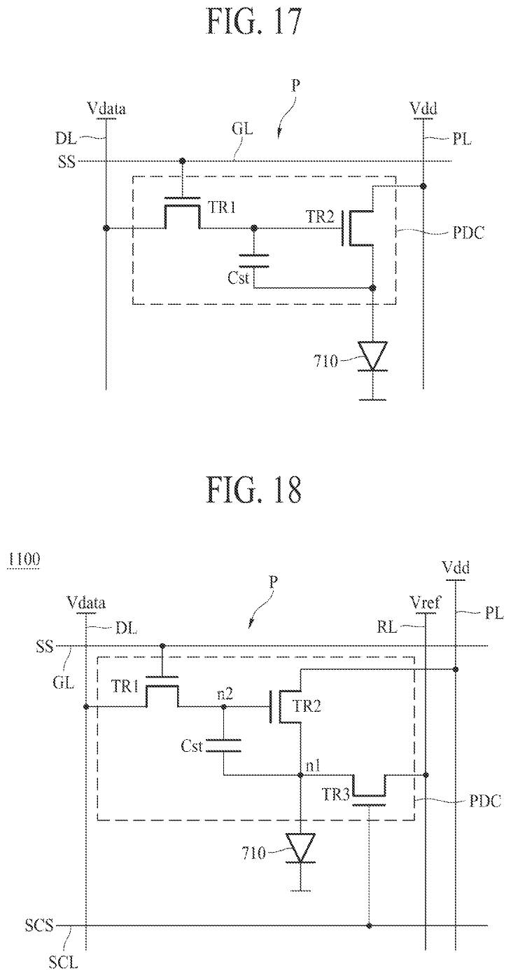

FIG. 17 is a circuit view illustrating any one pixel P of FIG. 15.

The circuit view of FIG. 17 is an equivalent circuit view for the pixel P of the display apparatus 1000 that includes an organic light emitting diode (OLED) as a display device 710.

Referring to FIG. 17, the pixel P includes a display device 710 and a pixel driving circuit PDC for driving the display device 710. In detail, the display apparatus 1000 according to one embodiment of the present disclosure may include a pixel driving circuit PDC on the base substrate 110.

The pixel driving circuit PDC of FIG. 17 includes a first thin film transistor TR1 that is a switching transistor and a second thin film transistor TR2 that is a driving transistor. The display apparatus 1000 according to another embodiment of the present disclosure may include at least one of the above-described thin film transistors 100, 200, 300, 400, 500 and 600.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display device 710, and the first thin film transistor TR1 controls the driving voltage Vdd. The driving voltage Vdd is a pixel driving voltage for driving the organic light emitting diode (OLED) that is the display device 710.

When the second thin film transistor TR2 is turned on by the scan signal SS applied from the gate driver 320 through the gate line GL, the data voltage Vdata supplied through the data line DL is supplied to a gate electrode of the second thin film transistor TR2 connected to the display device 710. The data voltage Vdata is charged in a storage capacitor Cst formed between the gate electrode and a source electrode of the second thin film transistor TR2.

The amount of a current supplied to the organic light emitting diode (OLED), which is the display device 710, through the second thin film transistor TR2 is controlled in accordance with the data voltage Vdata, whereby a gray scale of light output from the display device 710 may be controlled.

FIG. 18 is a circuit view illustrating any one pixel P of a display apparatus 1100 according to another embodiment of the present disclosure.

FIG. 18 is an equivalent circuit view for the pixel P of an organic light emitting display apparatus.

The pixel P of the display apparatus 1100 shown in FIG. 18 includes an organic light emitting diode (OLED) that is a display device 710 and a pixel driving circuit PDC for driving the display device 710. The display device 710 is connected with the pixel driving circuit PDC.

In the pixel P, signal lines DL, GL, PL, RL and SCL for supplying a signal to the pixel driving circuit PDC are disposed.

The data voltage Vdata is supplied to the data line DL, the scan signal SS is supplied to the gate line GL, the driving voltage Vdd for driving the pixel is supplied to the driving power line PL, a reference voltage Vref is supplied to a reference line RL, and a sensing control signal SCS is supplied to a sensing control line SCL.

The pixel driving circuit PDC includes, for example, a first thin film transistor TR1 (switching transistor) connected with the gate line GL and the data line DL, a second thin film transistor TR2 (driving transistor) for controlling a magnitude of a current output to the display device 710 in accordance with the data voltage Vdata transmitted through the first thin film transistor TR1, and a third thin film transistor TR3 (sensing transistor) for sensing characteristics of the second thin film transistor TR2.

The first thin film transistor TR1 is turned on by the scan signal SS supplied to the gate line GL to transmit the data voltage Vdata, which is supplied to the data line DL, to the gate electrode of the second thin film transistor TR2.

The third thin film transistor TR3 is connected to a first node n1 between the second thin film transistor TR2 and the display device 710 and the reference line RL, and thus is turned on or off by the sensing control signal SCS and senses characteristics of the second thin film transistor TR2, which is a driving transistor, for a sensing period.

A second node n2 connected with the gate electrode of the second thin film transistor TR2 is connected with the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2.

When the second thin film transistor TR2 is turned on, the current is supplied to the display device 710 through the second thin film transistor TR2 in accordance with the driving voltage Vdd for driving the pixel, whereby light is output from the display device 710.

The display apparatus 1100 according to another embodiment of the present disclosure may include at least one of the above-described thin film transistors 100, 200, 300, 400, 500 and 600.

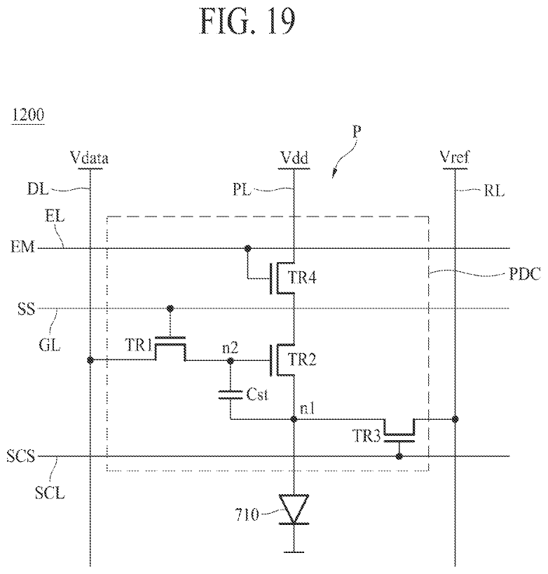

FIG. 19 is a circuit view illustrating any one pixel P of a display apparatus 1200 according to still another embodiment of the present disclosure.

The pixel P of the display apparatus 1200 shown in FIG. 19 includes an organic light emitting diode (OLED) that is a display device 710 and a pixel driving circuit PDC for driving the display device 710. The display device 710 is connected with the pixel driving circuit PDC.

The pixel driving circuit PDC includes thin film transistors TR1, TR2, TR3 and TR4.

In the pixel P, signal lines DL, EL, GL, PL, SCL and RL for supplying a driving signal to the pixel driving circuit PDC are disposed.

In comparison with the pixel P of FIG. 18, the pixel P of FIG. 19 further includes an emission control line EL. An emission control signal EM is supplied to the emission control line EL. Also, the pixel driving circuit PDC of FIG. 19 further includes a fourth thin film transistor TR4 that is an emission control transistor for controlling a light emission timing of the second thin film transistor TR2, in comparison with the pixel driving circuit PDC of FIG. 18.

The first thin film transistor TR1 is turned on by the scan signal SS supplied to the gate line GL to transmit the data voltage Vdata, which is supplied to the data line DL, to the gate electrode of the second thin film transistor TR2.

A storage capacitor Cst is positioned between the gate electrode of the second thin film transistor TR2 and the display device 710.

The third thin film transistor TR3 is connected to the reference line RL, and thus is turned on or off by the sensing control signal SCS and senses characteristics of the second thin film transistor TR2, which is a driving transistor, for a sensing period.

The fourth thin film transistor TR4 transfers the driving voltage Vdd to the second thin film transistor TR2 in accordance with the emission control signal EM or shields the driving voltage Vdd. When the fourth thin film transistor TR4 is turned on, a current is supplied to the second thin film transistor TR2, whereby light is output from the display device 710.

The pixel driving circuit PDC according to still another embodiment of the present disclosure may be formed in various structures in addition to the above-described structure. The pixel driving circuit PDC may include, for example, five or more thin film transistors.

According to the present disclosure, the following advantageous effects may be obtained.

Since the thin film transistor according to an embodiment of the present disclosure includes a channel protection layer including carbon (C), generation of an electron trap at an interface of the oxide semiconductor layer is alleviated or prevented. As these electronic traps are alleviated or prevented, partial damage and deterioration of the oxide semiconductor layer can be prevented, thereby improving the reliability of the thin film transistor.

The display apparatus according to an embodiment of the present disclosure including such a thin film transistor may have excellent reliability.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
a base substrate;
an oxide semiconductor layer on the base substrate;
a channel protection layer in contact with the oxide semiconductor layer; and
a gate electrode spaced apart from the oxide semiconductor layer and at least partially overlapping with the oxide semiconductor layer,
wherein the channel protection layer includes carbon.

2. The thin film transistor of claim 1, wherein the channel protection layer includes silicon (Si) and oxygen (O), and
a concentration of the carbon is in a range between 1% and 10% by atom (at %) based on components of the channel protection layer.

3. The thin film transistor of claim 1, wherein the channel protection layer is between the oxide semiconductor layer and the gate electrode.

4. The thin film transistor of claim 3, wherein the channel protection layer is in contact with a side surface of the oxide semiconductor layer.

5. The thin film transistor of claim 3, wherein the channel protection layer surrounds an upper surface and a side surface of the oxide semiconductor layer.

6. The thin film transistor of claim 3, further comprising a buffer layer between the base substrate and the oxide semiconductor layer, wherein the channel protection layer is in contact with a portion of the buffer layer.

7. The thin film transistor of claim 3, further comprising a gate insulating layer between the channel protection layer and the gate electrode.

8. The thin film transistor of claim 7, wherein the channel protection layer includes silicon (Si), oxygen (O) and hydrogen (H),
the gate insulating layer includes silicon (Si), oxygen (O) and hydrogen (H), and
a hydrogen concentration (at %) of the channel protection layer is lower than a hydrogen concentration (at %) of the gate insulating layer.

9. The thin film transistor of claim 8, wherein the gate insulating layer includes carbon (C), and
a carbon concentration (at %) of the channel protection layer is 100 times or more of a carbon concentration (at %) of the gate insulating layer.

10. The thin film transistor of claim 8, wherein the channel protection layer includes Non Bonding Oxygen (NBO),
the gate insulating layer includes Non Bonding Oxygen (NBO), and
a density of the Non Bonding Oxygen (NBO) of the channel protection layer is lower than a density of the Non Bonding Oxygen (NBO) of the gate insulating layer, wherein the Non Bonding Oxygen (NBO) refers to an atom ratio of Non Bonding Oxygen (NBO) to a total oxygen of a corresponding layer.

11. The thin film transistor of claim 7, wherein the channel protection layer has a thickness thinner than a thickness of the gate insulating layer, and
the channel protection layer has a thickness in a range between 1 nm and 10 nm.

12. The thin film transistor of claim 3, wherein the channel protection layer is in contact with the gate electrode, and
the channel protection layer has a thickness in a range between 10 nm and 100 nm.

13. The thin film transistor of claim 1, wherein the channel protection layer is between the oxide semiconductor layer and the base substrate.

14. The thin film transistor of claim 13, wherein the channel protection layer is in contact with an entire bottom surface of the oxide semiconductor layer.

15. The thin film transistor of claim 13, further comprising a buffer layer between the channel protection layer and the base substrate.

16. The thin film transistor of claim 15, wherein the channel protection layer includes silicon (Si), oxygen (O) and hydrogen (H),
the buffer layer includes silicon (Si), oxygen (O) and hydrogen (H), and
a hydrogen concentration (at %) of the channel protection layer is lower than the hydrogen concentration (at %) of the buffer layer.

17. The thin film transistor of claim 15, wherein the buffer layer includes carbon (C), and
a carbon concentration (at %) of the channel protection layer is 100 times or more of the carbon concentration (at %) of the buffer layer.

18. The thin film transistor of claim 15, wherein the channel protection layer includes Non Bonding Oxygen (NBO),
the buffer layer includes Non Bonding Oxygen (NBO) and
a density of the Non Bonding Oxygen (NBO) of the channel protection layer is lower than a density of the Non Bonding Oxygen (NBO) of the buffer layer.

19. The thin film transistor of claim 15, wherein the channel protection layer has a thickness thinner than a thickness of the buffer layer, and
the channel protection layer has a thickness in a range between 1 nm and 10 nm.

20. The thin film transistor of claim 13, wherein the channel protection layer is in contact with the base substrate, and
the channel protection layer has a thickness in a range between 10 nm and 100 nm.

21. The thin film transistor of claim 2, wherein the channel protection layer has a carbon (C) surface density fraction (C atoms/cm²) of 5.0×10¹⁵ or less:
a carbon (C) surface density fraction (C atoms/cm2) is calculated by a following equation:
Carbon (C) surface density fraction (C atoms/cm2)=surface density (total number of atoms/cm2)×carbon (C) concentration (C at %), and
the surface density means the surface density of the channel protection layer.

22. The thin film transistor of claim 1, wherein the channel protection layer includes a first channel protection layer and a second channel protection layer, and
the oxide semiconductor layer is between the first channel protection layer and the second channel protection layer.

23. The thin film transistor of claim 22, wherein the first channel protection layer is in contact with a lower surface of the oxide semiconductor layer, and
the second channel protection layer is in contact with an upper surface of the oxide semiconductor layer.

24. The thin film transistor of claim 23, at least one of the first channel protection layer and the second channel protection layer is in contact with a side surface of the oxide semiconductor layer, and
at least a part of the first channel protection layer and at least a part of the second channel protection layer are in contact with each other.

25. The thin film transistor of claim 22, further comprising a buffer layer between the first channel protection layer and the base substrate.

26. The thin film transistor of claim 22, further comprising a gate insulating layer between the second channel protection layer and the gate electrode.

27. The thin film transistor of claim 1, wherein the gate electrode is on the base substrate, and a gate insulation layer is on the gate electrode, and the channel protection layer is on the gate insulation layer.

28. The thin film transistor of claim 27, further comprising an etching barrier layer on the oxide semiconductor layer.

29. A display apparatus comprising the thin film transistor of claim 1.

30. A method of fabricating a thin film transistor, the method comprising:
preparing a base substrate;
forming an oxide semiconductor layer on the base substrate;
forming a channel protection layer on the base substrate; and
forming a gate electrode on the channel protection layer;
wherein the channel protection layer is deposited by an ALD or CVD method using a precursor, and
wherein the precursor includes at least one of di-isopropylaminosilane, (N,N-dimethylamino)trimethylsilane, vinyltrimethoxysilane, tetrakis(dimethylamino)silane, tris(dimethylamino)silane, bis(ethyl-methyl-amino)silane.

31. The method of claim 30, further comprising:
forming a buffer layer on the base substrate, and
forming a gate insulating layer on the oxide semiconductor layer.

32. The method of claim 30, wherein the forming the oxide semiconductor layer is performed before the forming the channel protection layer.

33. The method of claim 30, wherein the forming the channel protection layer is performed before the forming the oxide semiconductor layer.
